(19) United States
(12) Patent Application Publication
(10) Pub. No.: US 2025/0187902 A1
(43) Pub. Date: Jun. 12, 2025

(54) MEMS Device

(71) Applicant: SENSORTEK TECHNOLOGY CORP., Hsinchu County (TW)

(72) Inventors: Chao-Lin Cheng, Hsinchu County (TW); Shih-Wei Lee, Hsinchu County (TW)

(21) Appl. No.: 18/925,102

(22) Filed: Oct. 24, 2024

Related U.S. Application Data
(60) Provisional application No. 63/545,375, filed on Oct. 24, 2023.

(51) Int. Cl. B81B 3/00

(52) U.S. Cl. CPC B81B 3/0051; B81B 2201/0235; B81B 2203/0154; B81B 2203/0163; B81B 2203/0307; B81B 2203/04; B81B 2203/056; B81B 2203/058

(57) ABSTRACT

The present application discloses a MEMS device comprising a proof mass, an anchor, a main suspension, and a flexible stopper. The main suspension respectively connects to the proof mass and the anchor at both ends thereof. An end of the flexible stopper is connected to the anchor, and another end of the flexible stopper extends toward the proof mass. Thereby, the present application reduces the impact of adding the flexible stopper on the proof mass, maintaining the sensing sensitivity of the MEMS device.

### FIELD OF THE INVENTION

The present application relates to a MEMS device, particularly to a MEMS device including a stopper.

### BACKGROUND OF THE INVENTION

Due to the development of Microelectromechanical Systems (MEMS) technology, MEMS devices manufactured by integrating mechanical components and circuits using semiconductor technology are widely adopted in the consumer electronics industry for characteristics of low cost, compact size and so on.

MEMS devices may be categorized into various types based on their sensing methods. For example, a basic type of MEMS device is the inertial sensor, which comprises at least one proof mass. When the proof mass undergoes displacement due to acceleration, the distance between it and the sensing electrode will be changed. The distance changes are sensed by a capacitive sensing mechanism and converted into signals representing acceleration, allowing existing MEMS devices to calculate multi-axial direction accelerations using a single proof mass. The applicant's previous patent applications, such as Taiwan Patent Application No. 202240170 and No. 202411611, disclose related inertial sensor structures and operating methods thereof.

Taking such inertial sensors as an example, which are typically incorporated a hard stopper to limit the displacement of the proof mass. When high inertial forces are applied on the proof mass, the proof mass will collide with the hard stopper at high speed, tiny particles are potentially generated during the collision. The tiny particles may be dispersed within the sensing area of the inertial sensors during subsequent collisions, causing the sensing signal offsetting.

To settle the particle issue, some existing techniques include additional stopping structures to reduce the contact speed when the proof mass collides with the hard stopper, attempting to eliminate signal offset effects caused by tiny particles. However, the existing technologies are required with additional anchors for the additional stopping structures. Anchors are fixed points in MEMS devices, used to support other structures of the component or to be served as pivot points for the movement of other structures. Installing additional anchors will sacrifice the area of the proof mass, leading to a reduction in equivalent mass and thus decreasing the sensing sensitivity.

Sum up, existing techniques may need to sacrifice the sensing performance of MEMS devices to increase their reliability. Thus, there is still a need to improve MEMS devices including stoppers.

### SUMMARY OF THE INVENTION

An objective of the present application is to provide an improved MEMS device to address the issue of having to sacrifice the sensing performance of the MEMS device including stoppers to enhance their reliability.

To achieve the above objective, the present application provides a MEMS device comprising a proof mass, an anchor, a main suspension, and a flexible stopper. The main suspension respectively connects to the proof mass and the anchor at both ends. An end of the flexible stopper is connected to the anchor, and another end of the flexible stopper extends towards the proof mass. Additionally, the MEMS device may include a hard stopper, which is configured to block the displacement of the proof mass in the first axial direction.

By incorporating a flexible stopper, the MEMS device provides an elastic buffering effect against inertial forces in at least one direction, effectively preventing the proof mass from high-speed impacts with the hard stopper and thus eliminating potential signal offset effects caused by tiny particles generated during high-speed impacts.

Furthermore, the flexible stopper and the main suspension share an anchor in a common anchor design. Hereby, the addition of the flexible stopper significantly mitigates its impact on the proof mass, without excessively sacrificing the area and equivalent mass of the proof mass, thereby maintaining the sensing sensitivity of the MEMS device.

### BRIEF DESCRIPTION OF DRAWINGS

FIG. 1 is a schematic diagram of the MEMS device according to the first embodiment of the present application;

FIG. 2 is a partial operational schematic of the MEMS device according to the first embodiment of the present application;

FIG. 3 is a schematic diagram of the MEMS device according to the second embodiment of the present application;

FIG. 4 is a schematic diagram of the MEMS device according to the third embodiment of the present application;

FIG. 5 is a schematic diagram of the MEMS device according to the fourth embodiment of the present application;

FIG. 6 is a schematic diagram of the MEMS device according to the fifth embodiment of the present application;

FIG. 7 is a schematic diagram of the MEMS device according to the sixth embodiment of the present application;

FIG. 8 is a schematic diagram of the MEMS device according to the seventh embodiment of the present application; and

FIG. 9 is a schematic diagram of the MEMS device according to the eighth embodiment of the present application.

### DETAILED DESCRIPTION OF THE INVENTION

To provide the reviewers with a further understanding and recognition of the features and effects achieved by the present application, detailed explanations along with examples are provided as follows:

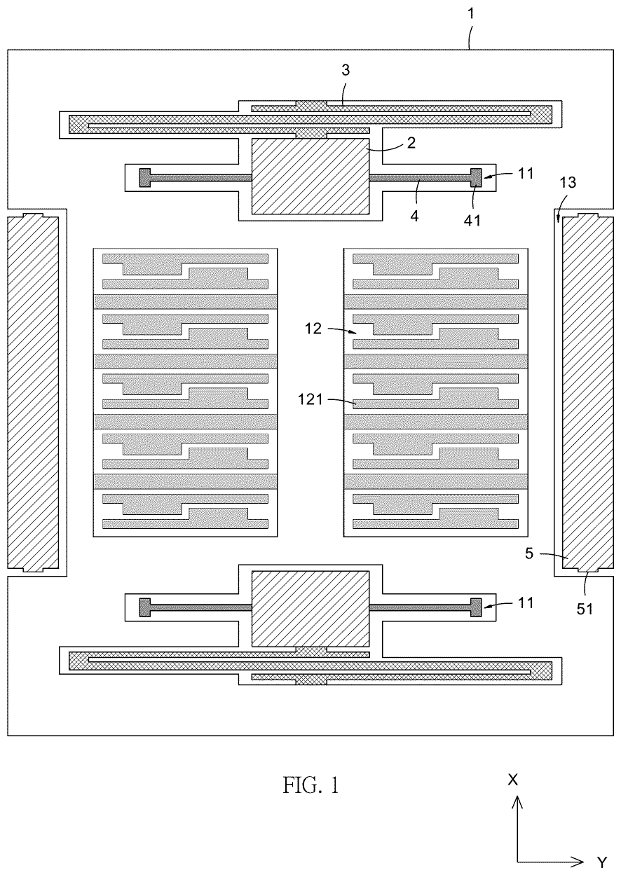

Please refer to FIG. 1, which is a schematic diagram of the MEMS device according to the first embodiment of the present application, showing the central device layer of the MEMS device. The substrate layer at the bottom and the cap layer at the top are not highlighted due to their inability to showcase the main improvements of the present application, thus are only described textually.

The MEMS device includes a proof mass 1, an anchor 2, a main suspension 3, a flexible stopper 4, and a hard stopper 5. The proof mass 1 may have a first notch 11 and a second notch 12, with the anchor 2, the main suspension 3, and the flexible stopper 4 disposed within the first notch 11. The second notch 12 accommodates the sensing electrode 121, which detects the motion of the proof mass 1 when subjected to an inertial force along the first axial direction X.

The anchor 2 may be connected to a substrate layer; alternatively, both sides of the anchor 2 may be connected to a cover layer and a substrate layer, forming an anchoring structure that serves as a fixed point in the MEMS device system architecture. In this embodiment, the main suspension 3 may be a suspension spring, with both ends connected to the proof mass 1 and the anchor 2 respectively, primarily facilitating linear motion along the first axial direction X, allowing the proof mass 1 to move along the first axial direction X.

An end of the flexible stopper 4 is connected to the anchor 2, and another end of the flexible stopper 4 extends towards the proof mass. The flexible stopper 4 includes a stop block 41, which is preferably disposed at the end of the flexible stopper 4 far from the anchor 2. The flexible stopper 4 is made from one or several materials that provide flexibility. Additionally, in this embodiment, the flexible stopper 4 may be flexible along the first axial direction X but more rigid along a second axial direction Y perpendicular to the first axial direction X. For example, the flexible stopper 4 may be composed of a long beam structure, extending along the second axial direction Y, providing greater rigidity along the second axial direction Y and flexibility in the direction perpendicular to the second axial direction Y in (including the first axial direction X). The flexibility of the flexible stopper 4, either overall or in specific sections, may be controlled through the design of its cross-section. For example, if greater flexibility is needed at the end of the flexible stopper 4 far from the anchor 2, the cross-sectional area may be reduced from the position of the anchor 2 towards another end of the flexible stopper 4.

The hard stopper 5, similar to the anchor 2, may be connected to the cover layer or substrate layer to form a fixed structure. In this embodiment, to make the component compact and easy to package, the proof mass 1 includes a third notch 13 for the placement of the hard stopper 5. The hard stopper 5 is designed to completely block the displacement of the proof mass 1 along the first axial direction X. Generally, the hard stopper 5 may have a contact part 51 formed by a special shape (such as a protrusion) or a special material (different from the material of the hard stopper 5 itself) along the first axial direction X towards the surface of the proof mass 1, to reduce the impact when the contact part 51 touches the proof mass 1.

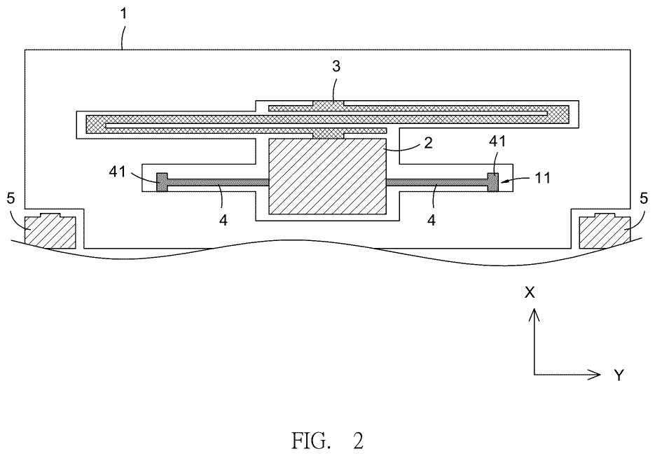

Please refer to FIG. 2, which is a partial operational schematic of the MEMS device according to the first embodiment of the MEMS device of the present application. When the inertial force acts on the proof mass 1 along the first axial direction X, the main suspension 3 will expand and contract to allow the proof mass 1 to move along the first axial direction X. When the inertial force reaches a certain level, the flexible stopper 4 may press against the proof mass 1 through the stop block 41, and since the flexible stopper 4 is flexible along the first axial direction X, it may slow down the displacement speed of the proof mass 1, or even stop its displacement.

Furthermore, if the inertial force is too high, even if the flexible stopper 4 cannot stop the displacement of the proof mass 1, it may still effectively slow down its displacement speed. Consequently, the displacement of the proof mass 1 will ultimately stop upon touching the hard stopper 5 or its contact part 51. However, since the flexible stopper 4 may slow down the displacement speed of the proof mass 1 during the process, it effectively prevents the proof mass 1 from impacting the hard stopper 5 at high speed, thereby avoiding the generation of tiny particles during high-speed impacts, which eliminates the potential signal-offset effects caused by such particles.

More importantly, in the first embodiment of the MEMS device of the present application, the anchor 2 connected to the flexible stopper 4 is the same as the anchor 2 connected to the main suspension 3. In other words, the flexible stopper 4 and the main suspension 3 share the same anchor 2 in the common anchor design. Consequently, compared to existing technologies that require additional anchors for extra stop structures, the first embodiment of the MEMS device in the present application only needs to add space in the first notch 11 of the proof mass 1 to accommodate the flexible stopper 4, compared to the need in existing technologies to create space for additional anchors, the present application significantly reduces the impact of adding the flexible stopper 4 on the proof mass 1 without excessively sacrificing the area and equivalent mass of the proof mass, thereby maintaining the sensitivity of the MEMS device.

In the previous description, it was not mentioned that, to form a fully differential system or simply for structural symmetry, the actual design of the MEMS device may include identical structures at corresponding positions on the proof mass 1. For example, another first notch 11′ may be created on the proof mass 1 to accommodate another set of main suspension and flexible stopper. Similarly, another second notch 12′ may be created on the proof mass 1 for another sensing electrode, and another third notch 13′ for another hard stopper.

It should be noted that in this embodiment, the first notch 11, the second notch 12, and the third notch 13 are all located within the proof mass 1. As more components are housed within the proof mass 1, the total area of the notches required increases, making it less feasible to set additional anchors for extra stop structures under these circumstances. In other words, under such circumstances, there is a higher demand for improvements in the embodiments of the MEMS device of the present application. Only through improvement of the common anchor design according to the present application, the impact of adding the flexible stopper 4 on the proof mass will be reduced, and the sensitivity of the MEMS device may be ensured.

Based on the inventive spirit of the first embodiment of the MEMS device of the present application, various alternative embodiments and implementations of the MEMS device may be realized:

First, referred to FIG. 1 again, in practical applications, MEMS devices may be used to form a tri-axial accelerometer. In other words, the proof mass 1, besides moving along the first axial direction X, may also be driven by other mechanisms (not shown, as there are numerous design methods for tri-axial accelerometers which are beyond the scope of the present application) to move in other directions, such as along the second axial direction Y. Under these circumstances, by altering the design of the flexible stopper 4, it may also be made flexible along the second axial direction Y, thereby providing an elastic buffering effect against the inertial forces along the second axial direction Y.

Specifically, by replacing the flexible stopper 4 from a long beam structure to a design that includes a serpentine structure (such as the aforementioned suspension spring), the flexible stopper 4 may also be made flexible along the second axial direction Y. Consequently, when the inertial force along the second axial direction Y is too high, the flexible stopper 4 may press against the proof mass 1 through the stop block 41 to provide an elastic buffering effect.

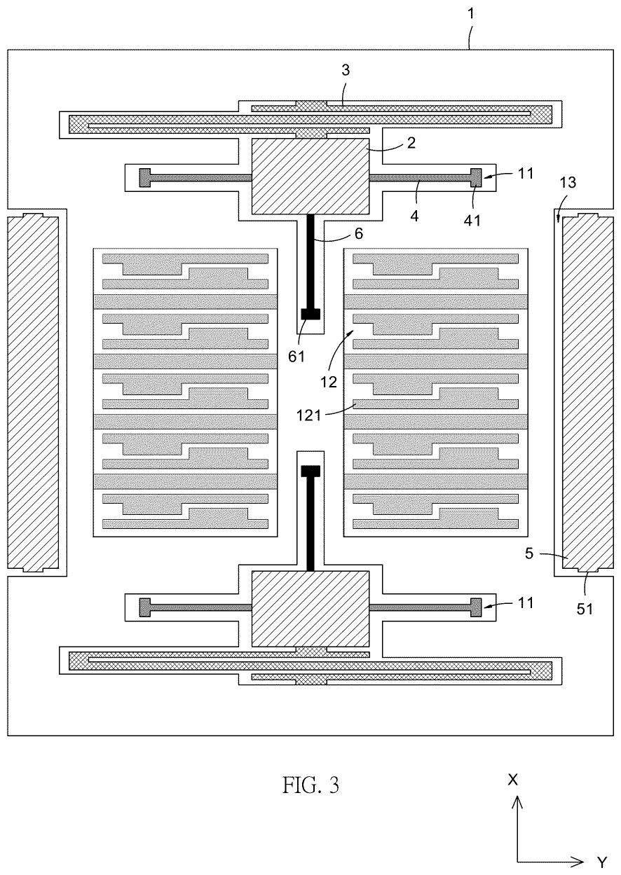

Alternatively, please refer to FIG. 3, which is a schematic diagram of the MEMS device according to the second embodiment of the present application. The difference from the first embodiment mentioned above is that the MEMS device also includes an auxiliary flexible stopper 6. The auxiliary flexible stopper 6 may also be placed in the first notch 11, with one end of the auxiliary flexible stopper 6 also connected to the anchor 2, and an auxiliary block 61 on the auxiliary flexible stopper 6, which is preferably disposed at the end of the auxiliary flexible stopper 6 far from the anchor 2. The auxiliary flexible stopper 6 may be a component that is flexible along the second axial direction Y but has better rigidity along the first axial direction X. For example, the auxiliary flexible stopper 6 may also be made from a long beam structure, extending along the first axial direction X, which provides better rigidity along the first axial direction X and flexibility perpendicular to the second axial direction Y.

Without altering the design of the flexible stopper 4, by additionally installing the auxiliary flexible stopper 6 along the second axial direction Y, the auxiliary flexible stopper 6 may still press against the proof mass 1 through the auxiliary block 61 when the inertial force along the second axial direction Y is too high, to provide an elastic buffering effect.

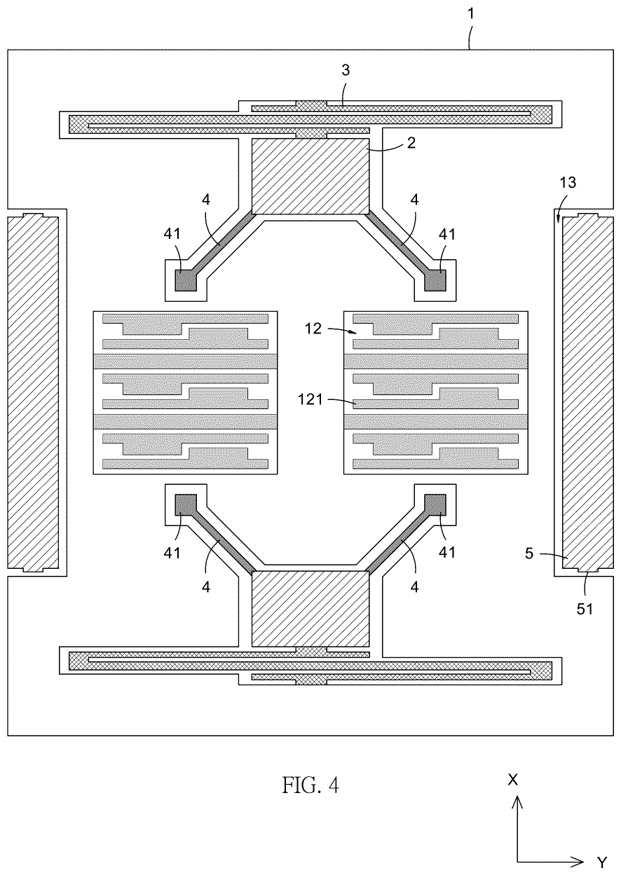

More alternatively, please refer to FIG. 4, which illustrates a schematic diagram of the MEMS device according to the third embodiment of the present application. The difference from the first embodiment is that by extending the long beam structure of the flexible stopper 4 in a specific direction on the X-Y plane formed by the first axial direction X and the second axial direction Y, but the specific direction is not parallel to either the first axial direction X or the second axial direction Y, the flexible stopper 4 may be made flexible in both the first axial direction X and the second axial direction Y respectively. Consequently, the flexible stopper 4 may provide an elastic buffering effect by contacting the stop block 41 with the proof mass 1 when the inertial force along either the first axial direction X or the second axial direction Y is too high.

Wherein, although in the diagram, the long beam structure of the flexible stopper 4 forms along an angle of approximately 45° with both of the first axial direction X and the second axial direction Y, the present application is not limited to this configuration. In fact, by designing the long beam structure of the flexible stopper 4 to have a larger angle with the first axial direction X, it may be ensured that the flexible stopper 4 has better flexibility along the first axial direction X. Consequently, when the stop block 41 contacts the proof mass 1 along the first axial direction X, the flexible stopper 4 is more likely to deform, providing a buffering effect. Conversely, if the angle between the long beam structure of the flexible stopper 4 and the first axial direction X is smaller, the flexible stopper 4 will have poorer flexibility along the first axial direction X. As a result, when the stop block 41 contacts the proof mass 1 along the first axial direction X, it may significantly reduce the displacement speed of the proof mass 1, thereby preventing the proof mass 1 from contacting the hard stopper 5.

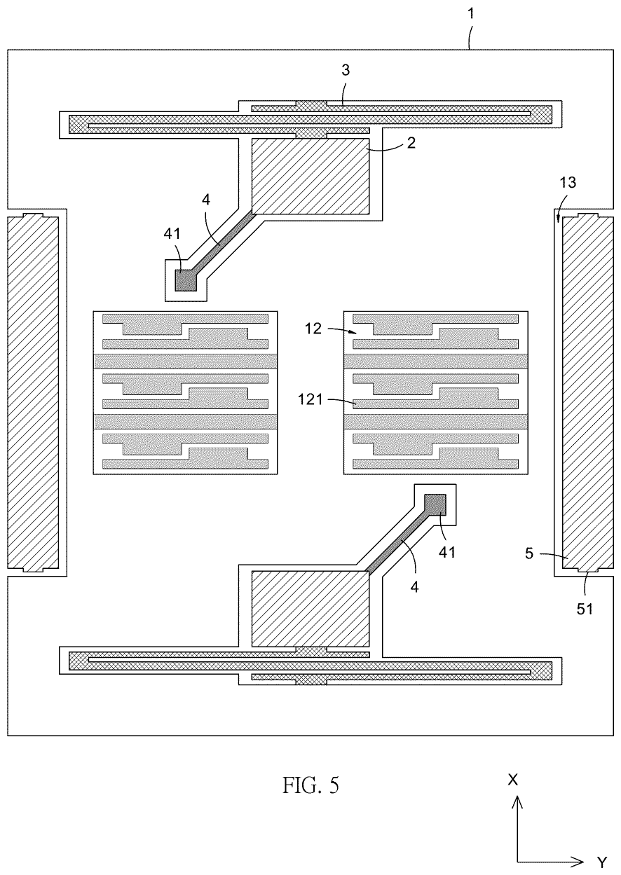

Please refer to FIG. 5, which is a schematic diagram of the MEMS device according to the fourth embodiment of the present application. The difference from the previous embodiments is that although it was described for structural symmetry of the MEMS device, the actual design of the MEMS device may include the same structure at the corresponding position on the proof mass 1. For this purpose, four flexible stoppers 4 were set up in the previous embodiments, and even two additional auxiliary flexible stoppers 6 were added in the second embodiment. However, under the spirit of the present application, if simulations or actual tests confirm that the elastic buffering effect of the flexible stoppers 4 is satisfactory, efforts should be made to reduce the number of flexible stoppers 4 to minimize the space of the first notch 11 in the proof mass 1 for accommodating the flexible stoppers 4. For example, in this embodiment, the two flexible stoppers 4 may also provide an elastic buffering effect by contacting the stop block 41 with the proof mass 1 when the inertial force along the first axial direction X or the second axial direction Y is too high, while also maintaining structural symmetry. In fact, if the user does not pursue structural symmetry, a single flexible stopper 4 may achieve the aforementioned technical effect.

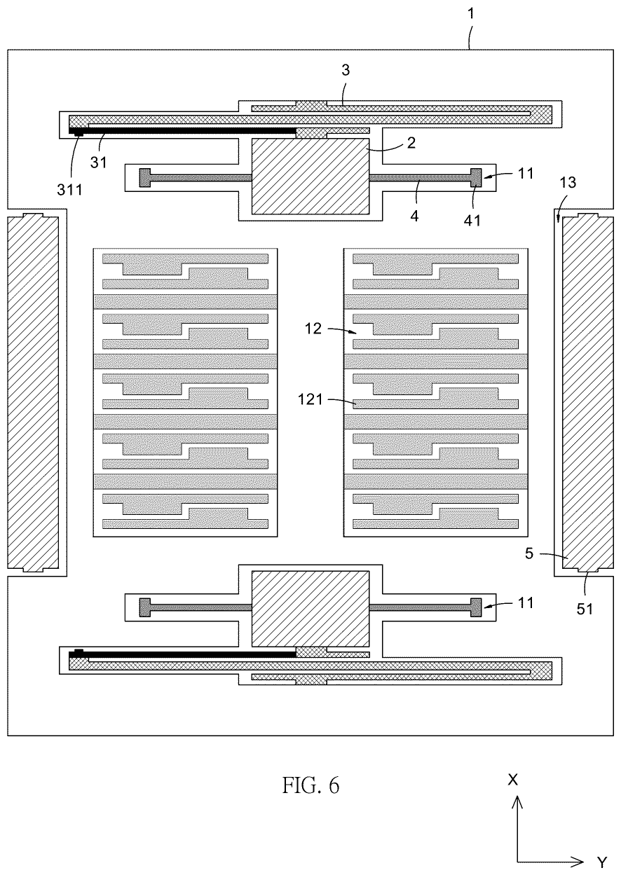

Please refer to FIG. 6, which is a schematic diagram of the MEMS device according to the fifth embodiment of the present application. The difference from the previous embodiments is that if simulations or actual tests confirm that the elastic buffering effect of the flexible stopper 4 is not yet satisfactory, besides changing the design of the flexible stopper 4, another approach could be to add an auxiliary flexible stopper 31 on the main suspension 3. In this embodiment, since the main suspension 3 is also a suspension spring capable of producing linear motion along the first axial direction X, by selecting a segment of the main suspension 3 as the auxiliary flexible stopper 31 and optionally placing an auxiliary block 311 on it, the auxiliary flexible stopper 31 may also provide an elastic buffering effect by contacting the auxiliary block 311 with the proof mass 1 when the inertial force along the first axial direction X is too high. Similar to the flexible stopper 4, the flexibility of the entire or specific sections of the auxiliary flexible stopper 31 may be controlled through the design of its cross-section. For example, if the section of the auxiliary flexible stopper 31 requires greater flexibility compared to other sections of the main suspension 3, the cross-sectional area of the auxiliary flexible stopper 31 may be made smaller than that of the other sections of the main suspension 3; and vice versa.

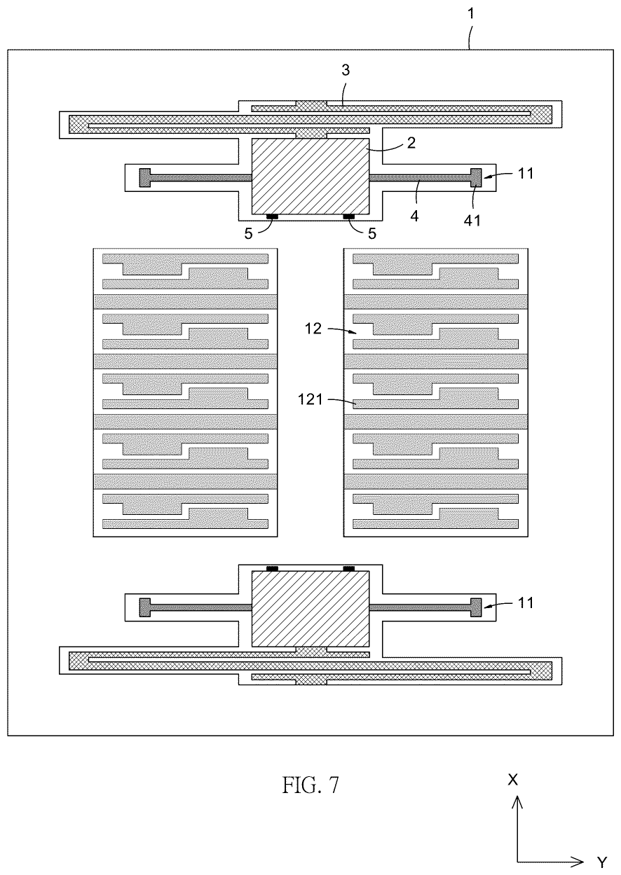

Please refer to FIG. 7, which is a schematic diagram of the MEMS device according to the sixth embodiment of the present application. The difference from the previous embodiments is that, by setting a flexible stopper 4 in each embodiment of the present application, it effectively prevents the proof mass 1 from high-speed impacts against the hard stopper 5. Consequently, under specific application conditions, it is possible to eliminate the need for large-sized hard stoppers 5 similar to those in the previous embodiments. In this embodiment, the hard stopper 5 may be replaced by a smaller protrusion, which may be directly placed on an exposed surface 21 of the anchor 2 along the first axial direction X towards the proof mass 1. Thus, the proof mass 1 does not require the previously mentioned third slot 13 for the placement of the hard stopper 5.

In fact, in this embodiment, by installing the flexible stopper 4 and modifying the hard stopper 5 to be connected to the anchor 2, the total area of the slots required for the proof mass 1 is even less than that of the existing technology without flexible stoppers. In other words, this embodiment not only effectively increases the area and equivalent mass of the proof mass but also enhances the sensing sensitivity of the MEMS device.

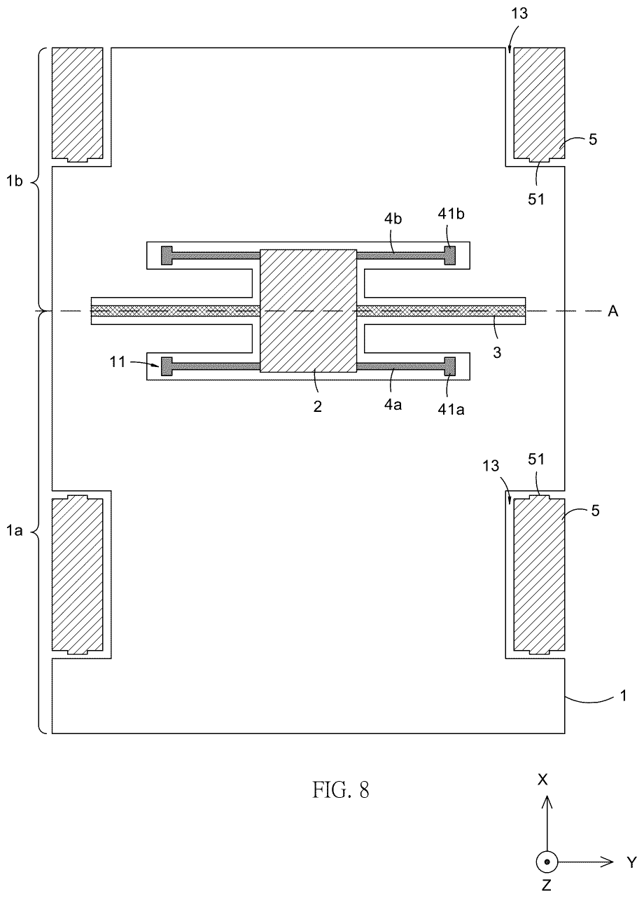

Please refer to FIG. 8, which is a schematic diagram of the MEMS device according to the seventh embodiment of the present application. The difference from the previous embodiments is that they disclosed how the flexible stopper 4 may be flexible along both the first axial direction X and the second axial direction Y, thereby providing an elastic buffering effect for inertial forces in different directions on the X-Y plane. However, for in-plane displacements on the X-Y plane, the improvements of the present application are also applicable to provide buffering effects for out-of-plane displacements.

Specifically, in this embodiment, the main suspension 3 may be a torsional spring, with both ends connected to the proof mass 1 and the anchor 2, respectively, and the main suspension 3 also facilitates rotational motion relative to a rotational axial direction A, allowing the proof mass 1 to rotate around the rotational axial direction A.

The proof mass 1 is divided into a first part 1a and a second part 1b on both sides of the rotating axial direction A. In this embodiment, the MEMS device includes a first flexible stopper 4a and a second flexible stopper 4b. The first flexible stopper 4a may be placed in the space of the first part 1a within the first notch 11, and the second flexible stopper 4b may be placed in the space of the second part 1b within the first notch 11. The remaining features of the first flexible stopper 4a and the second flexible stopper 4b are the same as those of the flexible stopper 4 in the first embodiment. Therefore, when the inertial force along the first axial direction X is too high, the first flexible stopper 4a and the second flexible stopper 4b may contact the proof mass 1 through the stop blocks 41a and 41b to provide an elastic buffering effect. Since the operating principle of this part is the same, it is not repeated here.

However, when the proof mass 1 rotates around the rotating axial direction A, causing its first part 1a to move out of plane along the third axial direction Z, the second part 1b will move out of plane in the direction opposite to the third axial direction Z. The third axial direction Z is perpendicular to both the first axial direction X and the second axial direction Y. If the inertial force causing this rotation is too high, the stop blocks 41a and 41b of either the first flexible stopper 4a or the second flexible stopper 4b may individually or collectively contact structures on the cover layer or component layer to provide an elastic buffering effect.

Accordingly, through the seventh embodiment of this MEMS device invention, the first flexible stopper 4a or the second flexible stopper 4b not only provides an elastic buffering effect against the inertial force along the first axial direction X but also against the inertial force causing out-of-plane movement perpendicular to the X-Y plane.

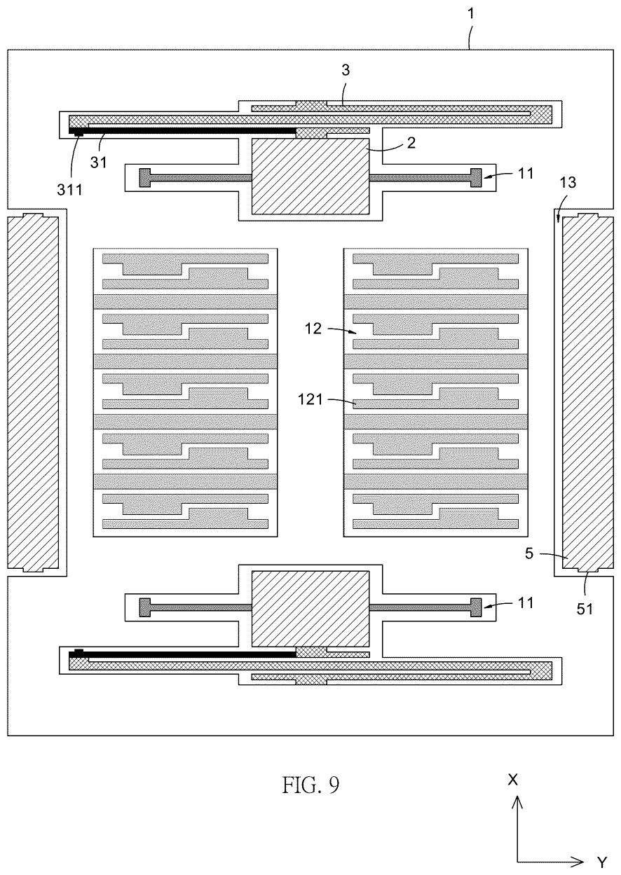

Please refer to FIG. 9, which illustrates a structural schematic of the MEMS device according to the eighth embodiment of the present application. The difference from the previous embodiments lies in the fact that, due to the wide application range of MEMS devices such as inertial sensors, in some applications where the inertial forces are too small, the previously mentioned flexible stopper 4 cannot be necessary to provide an elastic buffering effect. In such cases, an auxiliary flexible stopper 31 may be added to the main suspension 3 alone. In this embodiment, since the main suspension 3 is also a suspension spring capable of producing linear motion along the first axial direction X, by selecting a section of the main suspension 3 as the auxiliary flexible stopper 31, and depending on the situation, placing an auxiliary block 311 on one side of the auxiliary flexible stopper 31 towards the proof mass 1 along the first axial direction X, the auxiliary flexible stopper 31 may provide an elastic buffering effect by contacting the proof mass 1 with the auxiliary block 311 when the inertial force along the first axial direction X is too high.

The auxiliary flexible stopper 31 and the main suspension 3 may still be considered as sharing the anchor 2 in the common anchor design. Consequently, compared to existing technologies that require additional anchors for extra stop structures, the eighth embodiment of the MEMS device in the present application does not require additional space in the first notch 11 to accommodate the flexible stopper, thus maintaining the area and equivalent mass of the proof mass, and thereby preserving the sensitivity of the MEMS device.

More importantly, in each embodiment of the MEMS device in the present application, the flexible stopper and the main suspension adopt the common anchor design. Hereby, compared to existing technologies that require space for additional anchors, the addition of flexible stoppers in the present application significantly reduces the impact on the proof mass without excessively sacrificing its area and equivalent mass, thereby maintaining the sensitivity of the MEMS device.

Therefore, the present application indeed possesses novelty, progressiveness, and industrial applicability, undoubtedly meeting the requirements for a patent application under our national patent law. Accordingly, a patent application is hereby submitted, earnestly praying for the esteemed office to grant the patent soon.

However, the above descriptions are merely implementations of the present application and are not intended to limit the scope of the present application. Therefore, any equivalent modifications and variations in shape, structure, features, and spirit as described in the patent claims of the present application should be included within the scope of the patent application.

1. A MEMS device, comprising:
a proof mass;
an anchor;
a main suspension, respectively connected to the proof mass and the anchor at both ends; and
a flexible stopper, connected to the anchor at an end, and extending towards the proof mass at another end.

2. The MEMS device of claim 1, further comprising a hard stopper, configured to block the displacement of the proof mass in a first axial direction.

3. The MEMS device of claim 2, wherein the hard stopper includes a contact part, formed on a surface facing the proof mass along the first axial direction.

4. The MEMS device of claim 1, wherein the proof mass includes a first notch, in which the anchor, the main suspension, and the flexible stopper are disposed in the first notch.

5. The MEMS device of claim 4, wherein the first notch is located inside the proof mass.

6. The MEMS device of claim 1, wherein the proof mass includes a second notch, accommodating a sensing electrode.

7. The MEMS device of claim 2, wherein the proof mass includes a third notch, accommodating the hard stopper.

8. The MEMS device of claim 1, wherein the flexible stopper includes a stop block, which is disposed on the end of the flexible stopper far from the anchor.

9. The MEMS device of claim 2, wherein the flexible stopper is flexible along the first axial direction.

10. The MEMS device of claim 9, wherein the flexible stopper is flexible along a second axial direction perpendicular to the first axial direction.

11. The MEMS device of claim 10, wherein the flexible stopper extends in a direction not parallel to the first and second axial directions.

12. The MEMS device of claim 9, further comprising an auxiliary flexible stopper, also connected to the anchor at an end, and being flexible along a second axial direction perpendicular to the first axial direction.

13. The MEMS device of claim 2, wherein the main suspension is a suspension spring, allowing the proof mass to move along the first axial direction.

14. The MEMS device of claim 13, wherein the main suspension includes an auxiliary flexible stopper, and an auxiliary block is disposed on the auxiliary flexible stopper.

15. The MEMS device of claim 2, wherein the hard stopper is disposed on a surface of the anchor facing the proof mass along the first axial direction.

16. The MEMS device of claim 1, wherein the main suspension is a torsion spring, allowing the proof mass to rotate by a rotational axial direction.

17. The MEMS device of claim 16, wherein the proof mass comprises a first part and a second part disposed on both sides of the rotational axial direction, and the flexible stopper includes a first flexible stopper and a second flexible stopper, with the first flexible stopper disposed on the first part and the second flexible stopper disposed on the second part.

18. A MEMS device, comprising:
a proof mass;
an anchor;
a main suspension, respectively connected to the proof mass and the anchor at both ends, allowing the proof mass to move along a first axial direction;
wherein the main suspension includes an auxiliary flexible stopper, and an auxiliary block is disposed on the side of the auxiliary flexible stopper facing the proof mass along the first axial direction.
